(19) United States
(12) Patent Application Publication
(10) Pub. No.: US 2025/0336816 A1
(43) Pub. Date: Oct. 30, 2025

(54) SEMICONDUCTOR DEVICE INCLUDING AN INSULATING STRUCTURE

(71) Applicant: SAMSUNG ELECTRONICS CO., LTD., SUWON-SI (KR)

(72) Inventors: Minjeong CHOI, Suwon-si (KR); Hyungki CHO, Suwon-si (KR)

(21) Appl. No.: 18/948,175

(22) Filed: Nov. 14, 2024

(30) Foreign Application Priority Data
Apr. 30, 2024 (KR) 10-2024-0057909

(51) Int. Cl. H01L 23/528; H01L 23/532; H01L 29/423

(52) U.S. Cl. CPC H01L 23/5283; H01L 23/53295; H10D 64/512

(57) ABSTRACT

A semiconductor memory device comprising, a bit line extending in a first direction, a plurality of insulating structures disposed on the bit line and spaced apart from each other in the first horizontal direction, a semiconductor pattern disposed on sidewalls of the plurality of insulating structures, a gate electrode disposed on the semiconductor pattern and extending in a second horizontal direction intersecting the first horizontal direction, a gate insulating film disposed between the gate electrode and the semiconductor pattern, and a contact plug in contact with the semiconductor pattern, wherein a portion of the contact plug vertically overlaps the semiconductor pattern.

### CROSS-REFERENCE TO RELATED APPLICATION

This application claims priority under 35 U.S.C. § 119 to Korean Patent Application No. 10-2024-0057909, filed in the Korean Intellectual Property Office on Apr. 30, 2024, the entire contents of which are hereby incorporated by reference.

### BACKGROUND

### 1. Technical Field

The present disclosure relates to a semiconductor device, and more particularly to a semiconductor memory device including an insulating structure having a stepped shape.

### 2. Discussion of Related Art

A semiconductor device may be implemented as a component in an electronic device. Various types of semiconductor devices may be manufactured. For example, a memory device may be used to store and retrieve data, while a non-memory device may be used to control or amplify an electrical signal.

### SUMMARY

According to some embodiments of the present disclosure, a semiconductor device comprising, a bit line extending in a first horizontal direction, a plurality of insulating structures disposed on the bit line and spaced apart from each other in the first horizontal direction, a semiconductor pattern disposed on sidewalls of the plurality of insulating structures, a gate electrode disposed on the semiconductor pattern and extending in a second horizontal direction intersecting the first horizontal direction, a gate insulating film disposed between the gate electrode and the semiconductor pattern, and a contact plug disposed in contact with the semiconductor pattern along the sidewall of an insulating structure of the plurality of insulating structures.

According to some embodiments of the present disclosure, semiconductor memory device, comprising, a bit line extending in a first horizontal direction, a plurality of insulating structures disposed on the bit line and spaced apart from each other in the first horizontal direction, a semiconductor pattern disposed on the plurality of insulating structures, wherein the semiconductor pattern includes a first liner semiconductor pattern and a second liner semiconductor pattern spaced apart from each other in the first horizontal direction, a gate electrode disposed on the semiconductor pattern and extending in a second horizontal direction intersecting the first horizontal direction, a gate insulating film disposed between the semiconductor pattern and the gate electrode, and a contact plug disposed on the semiconductor pattern, wherein the contact plug is in contact with at least one of a side surface of the first liner semiconductor pattern or a side surface of the second liner semiconductor pattern.

According to some embodiments of the present disclosure, semiconductor memory device comprising, a bit line extending in a first horizontal direction, a plurality of insulating structures disposed on the bit line and spaced apart from each other in the first horizontal direction, wherein sidewalls of the plurality of insulating structures include a first side surface, a second side surface, and a step surface connecting the first side surface and the second side surface, a semiconductor pattern disposed on the sidewalls of the plurality of insulating structures, wherein the semiconductor pattern includes a first sub-semiconductor pattern disposed on the first side surface, a second sub-semiconductor pattern disposed on the second side surface, and a connection semiconductor pattern disposed on the step surface, a gate electrode disposed on the first sub-semiconductor pattern and extending in a second horizontal direction intersecting the first horizontal direction, a gate insulating film disposed between the gate electrode and the semiconductor pattern, a contact plug in contact with the second sub-semiconductor pattern, and a capacitor structure connected to the contact plug, wherein a portion of the contact plug overlaps the second sub-semiconductor pattern in the first horizontal direction.

The present disclosure provides a semiconductor memory device with improved electrical characteristics and reliability.

According to some embodiments of the present disclosure, the contact plug may be disposed on the side surface of the semiconductor pattern, and a contact area between the semiconductor pattern and the contact plug can be increased and resistance can be reduced.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view provided to explain a semiconductor device according to some embodiments of the present disclosure;

FIG. 2 is a cross-sectional view taken along line A-A of FIG. 1;

FIGS. 3 to 5 are enlarged views of the area Q1 of FIG. 2;

FIG. 6 is a diagram provided to explain a semiconductor device according to some embodiments of the present disclosure;

FIG. 7 is a diagram illustrating a semiconductor device according to some embodiments of the present disclosure;

FIG. 8 is a diagram illustrating a semiconductor device according to some embodiments of the present disclosure;

FIG. 9 is a diagram provided to explain a semiconductor device according to some embodiments of the present disclosure;

FIG. 10 is a diagram provided to explain a semiconductor device according to some embodiments of the present disclosure;

FIGS. 11 and 12 are diagrams provided to explain a semiconductor memory device according to some embodiments of the present disclosure;

FIGS. 13 to 21 are diagrams showing an intermediate stage of process, which are provided to explain a method for manufacturing a semiconductor device according to some embodiments of the present disclosure;

FIG. 22 is a diagram showing an intermediate stage of process, provided to explain a method for manufacturing a semiconductor device according to some embodiments of the present disclosure.

### DETAILED DESCRIPTION

Hereinafter, a semiconductor memory device and a method for manufacturing the same according to some embodiments of the present disclosure will be described in detail with reference to the drawings.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

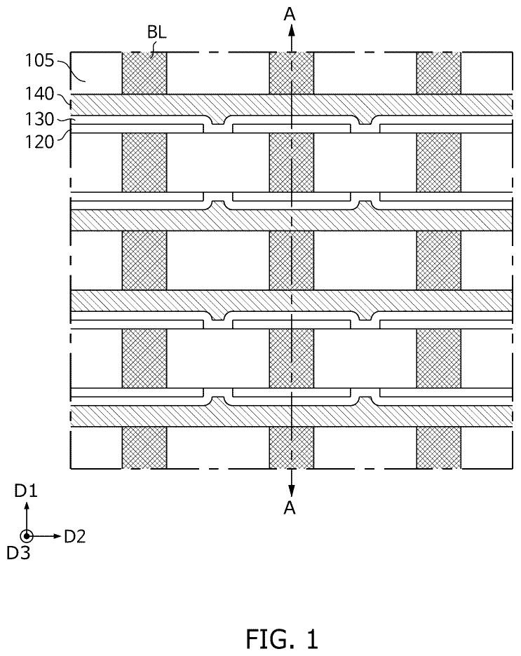

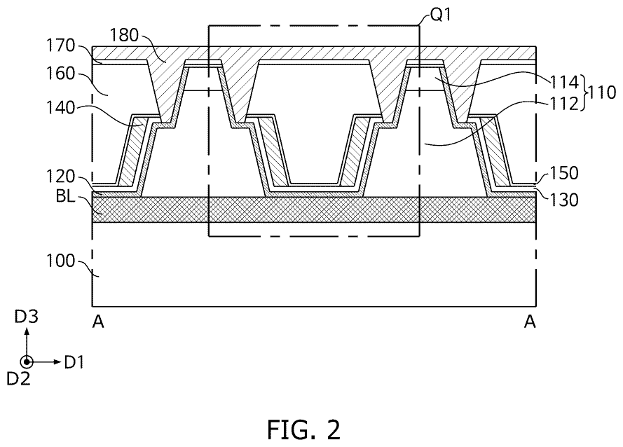

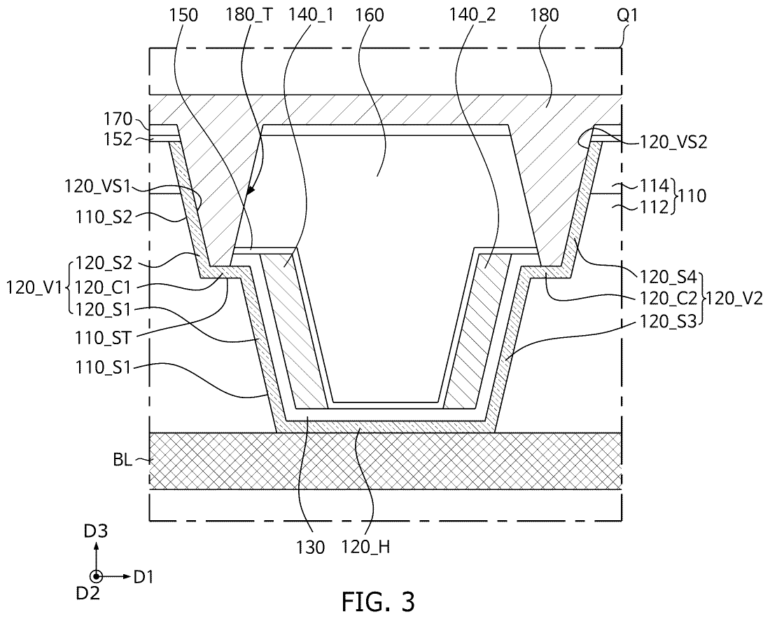

FIG. 1 is a plan view provided to explain a semiconductor device according to some embodiments of the present disclosure. FIG. 2 is a cross-sectional view taken along line A-A of FIG. 1. FIGS. 3, 4, and 5 are enlarged views of the area Q1 of FIG. 2.

The semiconductor device according to some embodiments of the present disclosure may be implemented in a semiconductor memory device. The semiconductor memory device according to some embodiments of the present disclosure may include memory cells including a vertical channel transistor (VCT).

Referring to FIGS. 1 to 5, the semiconductor device according to some embodiments of the present disclosure may include a substrate 100, a bit line BL, an insulating structure 110, a semiconductor pattern 120, a gate insulating film 130, a gate electrode 140, and a contact plug 180.

The substrate 100 may be a semiconductor substrate. For example, the substrate 100 may include silicon (Si), silicon germanium (SiGe), indium antimonide (InSb), lead telluride (PbTe), indium arsenide (InAs), indium phosphide (INP), gallium arsenide (GaAs), or gallium antimonide (GaSb). However, aspects are not limited to the above.

In some embodiments, a plurality of transistors connected to the bit line BL may be disposed in the substrate 100. For example, a sensing transistor, a transmission transistor, or a driving transistor may be disposed in the substrate 100. The type of the transistors may vary depending on the layout design of the semiconductor device.

In the drawings, a first direction D1 may be a first horizontal direction, a second direction D2 may be a second horizontal direction intersecting the first direction D1, and a third direction D3 may be a vertical direction, perpendicular to the first direction D1 and the second direction D2. The terms horizontal and vertical are relative terms and are not limiting.

A bit line BL may be disposed on the substrate 100. The bit line BL may extend on the substrate 100 in the first direction D1. Adjacent bit lines BL may be spaced apart from each other in the second direction D2. The second direction D2 may be a direction perpendicular to the first direction D1. A lower insulating layer 105 may be disposed between the adjacent bit lines BL.

For example, the bit line BL may include at least one of a doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), or a conductive metal silicide or a conductive metal oxide (e.g., PtO, RuO₂, IrO₂, SrRuO₃ (SRO), (Ba,Sr)RuO₃ (BSRO), CaRuO₃ (CRO), LSCO), but aspects are not limited thereto. The bit line BL is illustrated as a single layer, but aspects are not limited thereto. For example, the bit line BL may include a single layer or multiple layers of the materials described above.

In some embodiments, the bit line BL may include a semiconductor material. The bit line BL may include a two-dimensional (2D) semiconductor material. For example, the 2D material may include graphene, carbon nanotubes, or a combination thereof.

Portions of the insulating structure 110 may be disposed on at least one of the bit line BL or the lower insulating layer 105. The insulating structure 110 may extend in the second direction D2. Insulating structures 110 that at disposed adjacent to each other may be spaced apart from each other in the first direction D1.

The insulating structure 110 may include a first insulating layer 112 and a second insulating layer 114.

The first insulating layer 112 may be disposed on the bit line BL. The first insulating layer 112 may be in contact with the bit line BL. However, aspects are not limited to the above. For example, an etch stop layer may be disposed between the first insulating layer 112 and the bit line BL. The second insulating layer 114 may be disposed on the first insulating layer 112. The first insulating layer 112 may be disposed between the second insulating layer 114 and the bit line BL.

For example, the first insulating layer 112 may include an oxide-based insulating material. For example, the second insulating layer 114 may include a nitride-based insulating material. However, aspects are not limited to the above.

The insulating structure 110 may have a stepped shape. For example, a sidewall of the insulating structure 110 may include a first side surface 110_S1, a second side surface 110_S2, and a step surface 110_ST. The second side surface 110_S2 may be disposed above the first side surface 110_S1.

The first side surface 110_S1 and the second side surface 110_S2 may not be disposed on the same line. The first side surface 110_S1 and the second side surface 110_S2 may not be disposed on the same straight line. The slope of the first side surface 110_S1 may be the same as the slope of the second side surface 110_S2. In another aspect, the slope of the first side surface 110_S1 may be different from the slope of the second side surface 110_S2. For example, the slope of the first side surface 110_S1 may be greater than or less than the slope of the second side surface 110_S2.

The step surface 110_ST may connect the first side surface 110_S1 and the second side surface 110_S2. The step surface 110_ST may be parallel to the first direction D1, but aspects are not limited thereto. For example, the step surface 110_ST may not be parallel to the first direction D1. For example, the step surface 110_ST may have an upward slope connecting the first side surface 110_S1 and the second side surface 110_S2, wherein a lower end portion of the second side surface 110_S2 is disposed above an upper end portion of the first side surface 110_S1.

The step surface 110_ST may be disposed on the first insulating layer 112. The second insulating layer 114 may be disposed above the step surface 110_ST. However, aspects are not limited to the above. For example, the step surface 110_ST may be disposed at substantially the same level as a boundary surface between the first insulating layer 112 and the second insulating layer 114. As another example, the step surface 110_ST may be formed on the second insulating layer 114. For example, the boundary surface between the first insulating layer 112 and the second insulating layer 114 may be disposed below the step surface 110_ST.

The semiconductor pattern 120 may be disposed between the insulating structures 110 adjacent to each other in the first direction D1. The semiconductor pattern 120 may be disposed on the sidewall of the insulating structure 110 and an upper surface of the bit line BL. The semiconductor pattern 120 may extend along the upper surface of the bit line BL and the sidewalls of each of the insulating structures 110 facing each other in the first direction D1. The semiconductor pattern 120 may expose an upper surface of the second insulating layer 114.

The semiconductor pattern 120 may include a first liner semiconductor pattern 120_V1, a second liner semiconductor pattern 120_V2, and a horizontal semiconductor pattern 120_H.

The first liner semiconductor pattern 120_V1 may be disposed on a first sidewall of a first insulating structure of the insulating structures 110. The first liner semiconductor pattern 120_V1 may extend along the first sidewall of the first insulating structure of the insulating structures 110. The second liner semiconductor pattern 120_V2 may be disposed on a second sidewall of a second insulating structure of the insulating structures 110. The second liner semiconductor pattern 120_V2 may extend along the second sidewall of the second insulating structure of the insulating structure 110. The first liner semiconductor pattern 120_V1 and the second liner semiconductor pattern 120_V2 may be spaced apart from each other in the first direction D1. A first insulating structure of the plurality of insulating structures 110 may have a first liner semiconductor pattern 120 V1 and a second liner semiconductor pattern 120_V2 extending along opposite sidewalls thereof. The first liner semiconductor pattern 120_V1 and the second liner semiconductor pattern 120_V2 of the first insulating structure may be spaced apart from each other. For example, the first liner semiconductor pattern 120_V1 and the second liner semiconductor pattern 120_V2 of the first insulating structure may not be physically connected. Further, the first liner semiconductor pattern 120_V1 of the first insulating structure may face a second liner semiconductor pattern 120_V2 of a second insulating structure disposed adjacent to the first insulating structure.

The horizontal semiconductor pattern 120_H may be disposed on the bit line BL. The horizontal semiconductor pattern 120_H may be disposed on the bit line BL between the insulating structures 110. The horizontal semiconductor pattern 120_H may extend along the upper surface of the bit line BL. The horizontal semiconductor pattern 120_H may connect the first liner semiconductor pattern 120_V1 and the second liner semiconductor pattern 120_V2. For example, the first liner semiconductor pattern 120_V1 of the first insulating structure and the second liner semiconductor pattern 120_V2 of the second insulating structure may be connected by the horizontal semiconductor pattern 120_H.

It is illustrated that the horizontal semiconductor pattern 120_H and the bit line BL are in contact with each other, but aspects are not limited thereto. For example, a protective layer may be disposed between the horizontal semiconductor pattern 120_H and the bit line BL. For example, the protective layer may include a nitride.

In some embodiments, the horizontal semiconductor pattern 120_H may be separated in the first direction D1. For example, portions of the horizontal semiconductor pattern 120_H may be separated in the first direction D1.

The first liner semiconductor pattern 120_V1 may include a first sub-semiconductor pattern 120_S1, a second sub-semiconductor pattern 120_S2, and a first connection semiconductor pattern 120_C1. The first sub-semiconductor pattern 120_S1 may be disposed on the first side surface 110_S1 of the first insulating structure of the insulating structures 110. The second sub-semiconductor pattern 120_S2 may be disposed on the second side surface 110_S2 of the insulating structure 110. The first connection semiconductor pattern 120_C1 may be disposed on the step surface 110_ST of the first insulating structure of the insulating structures 110. The first connection semiconductor pattern 120_C1 may connect the first sub-semiconductor pattern 120_S1 and the second sub-semiconductor pattern 120_S2.

The second liner semiconductor pattern 120_V2 may be disposed on the second sidewall of the second insulating structure of the insulating structures 110 that is, in the first direction D1, opposite to the first sidewall on which the first liner semiconductor pattern 120_V1 is disposed. The second liner semiconductor pattern 120_V2 may include a third sub-semiconductor pattern 120_S3, a fourth sub-semiconductor pattern 120_S4, and a second connection semiconductor pattern 120_C2. The third sub-semiconductor pattern 120_S3 may be disposed on the first side surface 110_S1 of the second insulating structure of the insulating structures 110. The fourth sub-semiconductor pattern 120_S4 may be disposed on the second side surface 110_S2 of the insulating structure 110. The second connection semiconductor pattern 120_C2 may be disposed on the step surface 110_ST of the second insulating structure of the insulating structures 110. The second connection semiconductor pattern 120_C2 may connect the third sub-semiconductor pattern 120_S3 and the fourth sub-semiconductor pattern 120_S4.

In some embodiments, the concentration of an element included in the first sub-semiconductor pattern 120_S1 may be lower than the concentration of an element included in the second sub-semiconductor pattern 120_S2. A doping concentration of an element included in the first sub-semiconductor pattern 120_S1 may be lower than a doping concentration of the element included in the second sub-semiconductor pattern 120_S2. The concentration of an element included in the third sub-semiconductor pattern 120_S3 may be lower than the concentration of an element included in the fourth sub-semiconductor pattern 120_S4. A doping concentration of an element included in the third sub-semiconductor pattern 120_S3 may be lower than a doping concentration of the element included in the fourth sub-semiconductor pattern 120_S4. For example, the element may include tungsten (W). However, aspects are not limited to the above.

The semiconductor pattern 120 may include an oxide semiconductor. For example, the oxide semiconductor may include at least one of InₓGa_{y}Zn_{z}O, InₓGa_{y}Si_{z}O, InₓSn_{y}Zn_{z}O, InₓZn_{z}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O or InₓGa_{y}O, but aspects are not limited thereto. For example, the semiconductor pattern 120 may include an indium gallium zinc oxide (IGZO). The semiconductor pattern 120 may include a single layer or multiple layers of oxide semiconductor. The semiconductor pattern 120 may include an amorphous, crystalline, or polycrystalline oxide semiconductor.

In some embodiments, the semiconductor pattern 120 may have a bandgap energy greater than that of silicon. For example, the semiconductor pattern 120 may have a bandgap energy of about 1.5 to 5.6 eV. For example, the semiconductor pattern 120 having a bandgap energy of about 2.0 eV to 4.0 eV may have improved channel performance. For example, the semiconductor pattern 120 may be polycrystalline or amorphous, but aspects are not limited thereto. In some embodiments, the semiconductor pattern 120 may include a 2D semiconductor material. For example, the 2D semiconductor material may include graphene, carbon nanotube, or a combination thereof.

The gate electrode 140 may be disposed on the semiconductor pattern 120. The gate electrode 140 may be disposed between the first liner semiconductor pattern 120_V1 and the second liner semiconductor pattern 120_V2. The gate electrode 140 may intersect the bit line BL (see FIG. 1). The gate electrode 140 may extend in the second direction D2.

The gate electrode 140 may include a first sub-gate electrode 140_1 and a second sub-gate electrode 140_2. The first sub-gate electrode 140_1 may be spaced apart from the second sub-gate electrode 140_2 in the first direction D1. The first sub-gate electrode 140_1 may be disposed on the first sub-semiconductor pattern 120_S1. The first sub-gate electrode 140_1 may control a transistor that uses the first liner semiconductor pattern 120_V1 as a channel region. The second sub-gate electrode 140_2 may be disposed on a third sub-semiconductor pattern 120_S3. The second sub-gate electrode 140_2 may control a transistor that uses the second liner semiconductor pattern 120_V2 as a channel region.

In some embodiments, with respect to the upper surface of the bit line BL, an upper surface of the gate electrode 140 may be disposed at a height greater than a height of the step surfaces 110_ST of the plurality of insulating structures 110. However, aspects are not limited to the above. For example, with respect to the upper surface of the bit line BL, the upper surface of the gate electrode 140 may be disposed in substantially the same plane or at a lower height than the step surfaces 110_ST of the plurality of insulating structures 110.

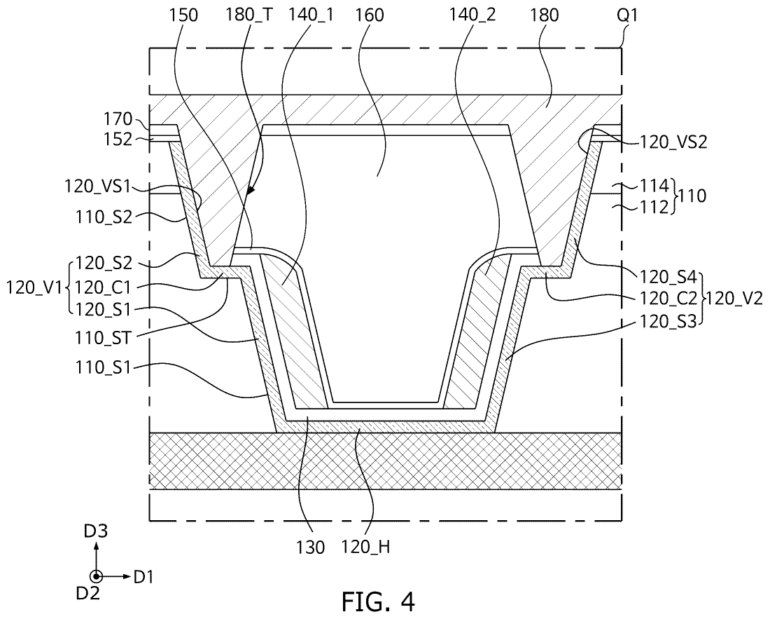

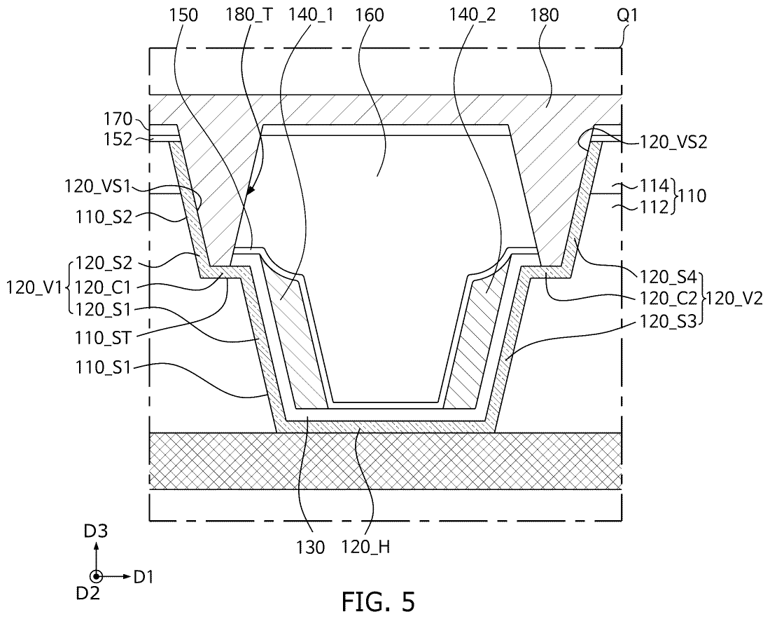

In some embodiments, as illustrated in FIG. 3, the upper surfaces of the first sub-gate electrode 140_1 and the second sub-gate electrode 140_2 may be flat. In some embodiments, as illustrated in FIG. 4, the upper surfaces of the first sub-gate electrode 140_1 and the second sub-gate electrode 140_2 may be convexly rounded. In some embodiments, as illustrated in FIG. 5, the upper surfaces of the first sub-gate electrode 140_1 and the second sub-gate electrode 140_2 may be concavely rounded.

For example, the gate electrode 140 may include at least one of a doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), or a conductive metal silicide or a conductive metal oxide (e.g., PtO, RuO₂, IrO₂, SrRuO₃ (SRO), (Ba, Sr)RuO₃ (BSRO), CaRuO₃ (CRO), LSCO), but aspects are not limited thereto. The gate electrode 140 may include a single layer or multiple layers of the materials described herein.

In some embodiments, the gate electrode 140 may include the 2D semiconductor material. For example, the 2D semiconductor material may include graphene, carbon nanotube, or a combination thereof.

The gate insulating film 130 may be disposed between the semiconductor pattern 120 and the gate electrode 140. For example, the gate insulating film 130 may be disposed between the first liner semiconductor pattern 120_V1 and the first sub-gate electrode 140_1 and between the second liner semiconductor pattern 120_V2 and the second sub-gate electrode 140_2. Examples are described herein with reference to the gate insulating film 130 disposed between the first liner semiconductor pattern 120_V1 and the first sub-gate electrode 140_1.

The gate insulating film 130 may extend along the first sub-semiconductor pattern 120_S1. An upper portion of the gate insulating film 130 may be disposed on at least a portion of the first connection semiconductor pattern 120_C1, but aspects are not limited thereto. The gate insulating film 130 may extend along the first sub-semiconductor pattern 120_S1, and the upper portion of the gate insulating film 130 may expose the first connection semiconductor pattern 120_C1. The gate insulating film 130 may separate the first liner semiconductor pattern 120_V1 from the first sub-gate electrode 140 1.

The gate insulating film 130 may have a horizontal portion. The horizontal portion of the gate insulating film 130 may be disposed on the horizontal semiconductor pattern 120_H. The horizontal portion of the gate insulating film 130 may extend along the horizontal semiconductor pattern 120_H. However, aspects are not limited to the above. For example, portions of the gate insulating film 130 may be separated and spaced apart from each other in the first direction D1. For example, a first portion of the gate insulating film 130 disposed between the first liner semiconductor pattern 120_V1 and the first sub-gate electrode 140_1 and a second portion of the gate insulating film 130 disposed between the second liner semiconductor pattern 120_V2 and the second sub-gate electrode 140_2 may be separated from each other in the first direction D1.

The gate insulating film 130 may include at least one of silicon oxide, silicon oxynitride, or a high dielectric material having a dielectric constant higher than that of silicon oxide. The high dielectric material may include a metal oxide or a metal oxynitride. For example, the high dielectric material of the gate insulating film 130 may include at least one of HfO₂, HfSiO, HfSiON, HfTaO, HfTiO, HfZrO, ZrO₂ or Al₂O₃, but aspects are not limited thereto.

In some embodiments, the semiconductor device may further include a gate separation liner 150. The gate separation liner 150 may be disposed on the gate electrode 140 and the gate insulating film 130. The gate separation liner 150 may extend along the upper surface and side surfaces of the gate electrode 140 and along a portion of the gate insulating film 130. The gate separation liner 150 may include an insulating material.

In some embodiments, the semiconductor device may further include a gate separation pattern 160. The gate separation pattern 160 may be disposed on the gate electrode 140 and the gate insulating film 130. The gate separation pattern 160 may be disposed on the gate separation liner 150. In some embodiments, the boundary between the gate separation pattern 160 and the gate separation liner 150 may not be distinguished.

The gate separation pattern 160 may separate the first sub-gate electrode 140_1 and the second sub-gate electrode 140_2. The gate separation pattern 160 may include an insulating material. For example, the gate separation pattern 160 may electrically isolate the first sub-gate electrode 140_1 from the second sub-gate electrode 140_2.

A contact plug trench 180_T may be disposed between the gate separation pattern 160 and the insulating structure 110. For example, the contact plug trench 180_T may be defined by a boundary surface including the gate separation pattern 160, the second sub-semiconductor pattern 120_S2, the first connection semiconductor pattern 120_C1, the gate insulating film 130, and the gate separation liner 150. The contact plug trench 180_T may have a tapered shape. However, aspects are not limited to the above. For example, the width of the contact plug trench 180_T may be constant. The contact plug trench 180_T may be defined by a boundary surface including portions of the gate separation pattern 160, the second sub-semiconductor pattern 120_S2, the first connection semiconductor pattern 120_C1, the gate insulating film 130, and the gate separation liner 150. The contact plug trench 180_T may be defined by a boundary surface including portions of one or more of the gate separation pattern 160, the second sub-semiconductor pattern 120_S2, the first connection semiconductor pattern 120_C1, the gate insulating film 130, or the gate separation liner 150.

The contact plug 180 may be disposed on the contact plug trench 180_T. The contact plug 180 may fill at least a portion of the contact plug trench 180_T.

The contact plug 180 may be in contact with a side surface of the semiconductor pattern 120. The contact plug 180 may be disposed in contact with the semiconductor pattern 120 along the sidewall of an insulating structure of the plurality of insulating structures 110. The contact plug 180 disposed on the first liner semiconductor pattern 120_V1 may be in contact with a side surface 120_VS1 of the first liner semiconductor pattern 120_V1. For example, the contact plug 180 may be in contact with the second sub-semiconductor pattern 120_S2 and the first connection semiconductor pattern 120_C1.

The contact plug 180 disposed on the second liner semiconductor pattern 120_V2 may be in contact with a side surface 120_VS2 of the second liner semiconductor pattern 120_V2. For example, the contact plug 180 may be in contact with the fourth sub-semiconductor pattern 120_S4 and the second connection semiconductor pattern 120_C2. Examples are described herein with reference to the contact plug 180 disposed on the first liner semiconductor pattern 120_V1.

The contact plug 180 may overlap the second sub-semiconductor pattern 120_S2 in the first direction D1. The contact plug 180 may be in contact with the second sub-semiconductor pattern 120_S2. A lower portion of the contact plug 180 may be in contact with the first connection semiconductor pattern 120_C1. However, aspects are not limited to the above. For example, the lower portion of the contact plug 180 may not be in contact with the first connection semiconductor pattern 120_C1. The gate insulating film 130 may be disposed between the lower portion of the contact plug 180 and the first connection semiconductor pattern 120_C1.

A smaller contact area between the contact plug 180 and the semiconductor pattern 120 may result in a larger resistance between the contact plug 180 and the semiconductor pattern 120. On the other hand, in the semiconductor device according to some embodiments of the present disclosure, the contact plug 180 may be in contact with the side surfaces of the first and second liner semiconductor patterns 12O_V1 and 120_V2, respectively. Accordingly, the resistance between the contact plug 180 and the semiconductor pattern 120 can be reduced, and the electrical characteristics of the semiconductor device can be improved.

The contact plug 180 may be formed of a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, or RuOₓ, or a combination thereof, but aspects are not limited thereto.

In some embodiments, the semiconductor device may further include a capping liner 152 and a capping layer 170.

The capping liner 152 may be disposed on the insulating structure 110 and the semiconductor pattern 120. The capping liner 152 may be disposed on an upper surface of the insulating structure 110. The upper surface of the insulating structure 110 may be an upper surface of the second insulating layer 114. The capping liner 152 may be disposed on an upper surface of the first liner semiconductor pattern 120_V1. The capping liner 152 may cover the upper surface of the first liner semiconductor pattern 120_V1. The upper surface of the first liner semiconductor pattern 120_V1 may be disposed in substantially the same plane as the upper surface of the insulating structure 110.

The capping layer 170 may be disposed on the insulating structure 110, the semiconductor pattern 120, and the gate separation pattern 160. The capping layer 170 may be disposed on the capping liner 152. The capping liner 152 may be disposed between the capping layer 170 and the insulating structure 110. The capping layer 170 may be disposed on the upper surface of the first liner semiconductor pattern 120_V1. The capping layer 170 may overlap the first liner semiconductor pattern 120_V1 in the third direction D3.

In some embodiments, the capping liner 152 may not be disposed between the insulating structure 110 and the capping layer 170. For example, the upper surface of the insulating structure 110 and the upper surface of the first liner semiconductor pattern 120_V1 may be in contact with the capping layer 170.

In some embodiments, the capping liner 152 and the capping layer 170 may not be disposed on the insulating structure 110. For example, the contact plug 180 may be disposed on the upper surface of the first liner semiconductor pattern 120_V1. The contact plug 180 may be in contact with the upper surface and the side surface 120_VS1 of the first liner semiconductor pattern 120_V1.

The capping liner 152 and the capping layer 170 may include an insulating material. The capping liner 152 may include the same material as the gate separation liner 150.

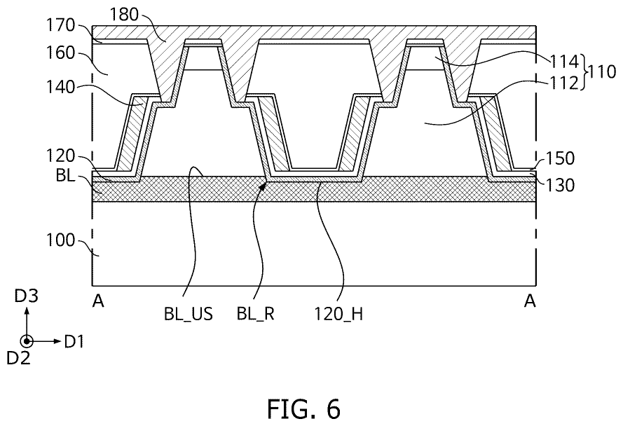

FIG. 6 is a diagram provided to explain a semiconductor device according to some embodiments of the present disclosure.

Referring to FIG. 6, in the semiconductor device according to some embodiments, the bit line BL may include a recess BL_R. The recess BL_R may be formed on the bit line BL. With respect to an upper surface of the substrate 100, the recess BL_R may be disposed at a lower height than the upper surface BL_US of the bit line BL.

The semiconductor pattern 120 may be disposed on the bit line BL. The horizontal semiconductor pattern 120_H may be disposed in the recess BL_R and in contact with the bit line BL. The horizontal semiconductor pattern 120_H may fill at least a portion the recess BL_R. A portion where the first liner semiconductor pattern 120_V1 and the horizontal semiconductor pattern 120_H are connected to each other, and a portion where the second liner semiconductor pattern 120_V2 and the horizontal semiconductor pattern 120_H are connected to each other may be disposed on the recess BL_R.

The horizontal semiconductor pattern 120_H may be disposed in the recess BL_R such that a contact area between the bit line BL and the semiconductor pattern 120 can be increased. Accordingly, electrical characteristics of a transistor that uses the semiconductor pattern 120 as a channel can be improved.

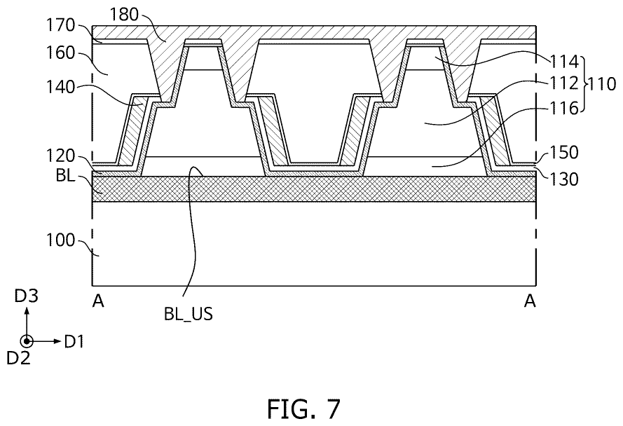

FIG. 7 is a diagram illustrating a semiconductor device according to some embodiments of the present disclosure.

Referring to FIG. 7, in the semiconductor device according to some embodiments, the insulating structure 110 may include the first insulating layer 112, the second insulating layer 114, and a third insulating layer 116.

The third insulating layer 116 may be disposed on the bit line BL. The third insulating layer 116 may be in contact with the upper surface BL_US of the bit line BL. The first insulating layer 112 may be disposed on the third insulating layer 116. The second insulating layer 114 may be disposed on the first insulating layer 112. The first insulating layer 112 may be disposed between the second insulating layer 114 and the third insulating layer 116.

For example, the first insulating layer 112 may include an oxide-based insulating material. For example, the second insulating layer 114 may include a nitride-based insulating material. For example, the third insulating layer 116 may include a nitride-based insulating material. In some embodiments, the second insulating layer 114 and the third insulating layer 116 may include the same material.

The third insulating layer 116 may be a passivation film formed on the bit line BL. For example, the third insulating layer 116 may be formed on the upper surface BL_US of the bit line BL such that diffusion of a contaminant to the bit line BL can be inhibited or prevented. For example, the third insulating layer 116 may be formed on the upper surface BL_US of the bit line BL such that diffusion of oxygen O₂ to the bit line BL can be inhibited or prevented.

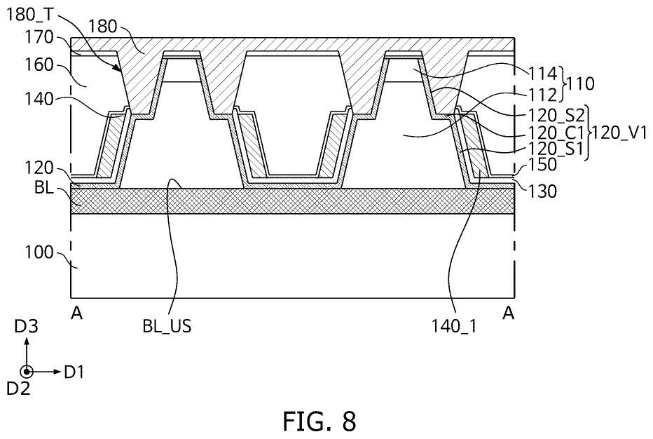

FIG. 8 is a diagram illustrating a semiconductor device according to some embodiments of the present disclosure.

Referring to FIG. 8, in the semiconductor device according to some embodiments, the contact plug trench 180_T may be disposed between the gate separation pattern 160 and the insulating structure 110. The contact plug trench 180_T may be defined as a boundary surface between the gate separation pattern 160, the second sub-semiconductor pattern 120_S2, and the first connection semiconductor pattern 120_C1. The contact plug trench 180_T may expose the first connection semiconductor pattern 120_C1. The contact plug trench 180_T may have a tapered shape.

The contact plug 180 may be disposed on the contact plug trench 180_T. The contact plug 180 may fill at least a portion the contact plug trench 180_T.

The contact plug 180 may be in contact with the side surface 120_VS1 of the first liner semiconductor pattern 120_V1. For example, the contact plug 180 may be in contact with the second sub-semiconductor pattern 120_S2 and the first connection semiconductor pattern 120_C1. The width of a bottom surface of the contact plug 180 in the first direction DI may be substantially the same as the width of the first connection semiconductor pattern 120_C1 in the first direction D1.

The gate electrode 140 may be disposed on the semiconductor pattern 120. For example, the first sub-gate electrode 140_1 may be disposed on the first liner semiconductor pattern 120_V1. The first sub-gate electrode 140_1 may not overlap the contact plug 180 in the first direction D1. In other words, with respect to the upper surface of the bit line BL, a distance to the upper surface of the first sub-gate electrode 140_1 may be substantially the same as a distance to the bottom surface of the contact plug 180. However, aspects are not limited to the above. With respect to the upper surface of the bit line BL, the distance to the upper surface of the first sub-gate electrode 140_1 may be less than the distance to the bottom surface of the contact plug 180.

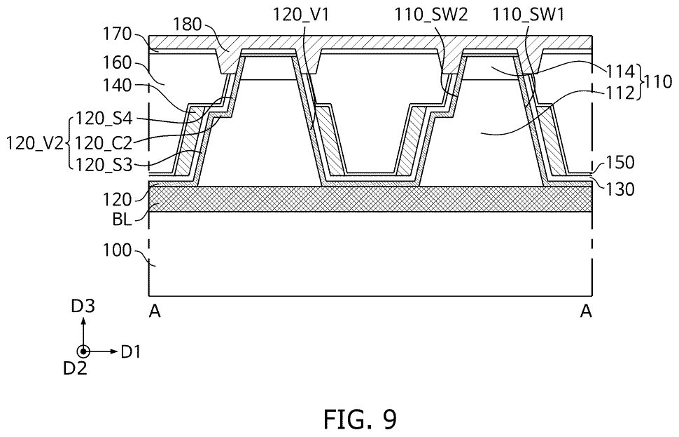

FIG. 9 is a diagram provided to explain a semiconductor device according to some embodiments of the present disclosure.

Referring to FIG. 9, in the semiconductor device according to some embodiments, the insulating structure 110 may have an asymmetric structure. For example, sidewalls of the insulating structure 110 in the first direction D1 may have an asymmetric structure.

A first sidewall 110_SW1 of the insulating structure 110 may omit a stepped shape. The first sidewall 110_SW1 of the insulating structure 110 may have a linear shape. The first sidewall 110_SW1 of the insulating structure 110 may have a linear shape extending in one direction, but is not limited hereto. For example, the first sidewall 110_SW1 of the insulating structure 110 may have a curved shaped. First sidewalls 110_SW1 may be disposed on the same surfaces of the insulating structures 110 disposed spaced apart in the first direction D1. A second sidewall 110_SW2 of the insulating structure 110 may have a stepped shape. The second sidewall 110 SW2 of the insulating structure 110 may include a step surface. The description of the second sidewall 110_SW2 of the insulating structure 110 may be the same as that described with reference to FIGS. 1 to 3.

The first liner semiconductor pattern 120_V1 may be disposed on the first sidewall 110_SW1 of the insulating structure 110. The first liner semiconductor pattern 120_V1 may conformally extend along the first sidewall 110_SW1 of the insulating structure 110.

The contact plug 180 may be disposed on the contact plug trench 180_T. The contact plug 180 may be in contact with each of the side surface of the first liner semiconductor pattern 120_V1 and the side surface of the second liner semiconductor pattern 120_V2. The contact plug 180 disposed on the second liner semiconductor pattern 120_V2 is described herein.

The contact plug 180 may be in contact with the fourth sub-semiconductor pattern 120_S4. The contact plug 180 may vertically overlap the second connection semiconductor pattern 120_C2. The contact plug 180 may not be in contact with the second connection semiconductor pattern 120_C2. The gate insulating film 130 may be disposed between the contact plug 180 and the second connection semiconductor pattern 120_C2.

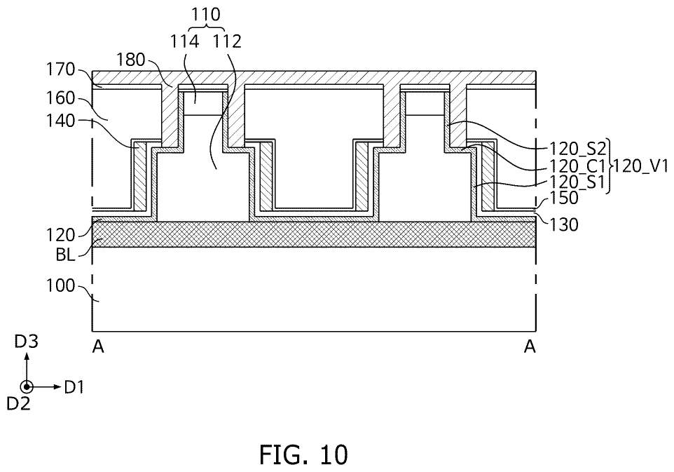

FIG. 10 is a diagram provided to explain a semiconductor device according to some embodiments of the present disclosure.

Referring to FIG. 10, in the semiconductor device according to some embodiments, the sidewall of the insulating structure 110 may have a stepped shape. The sidewall of the insulating structure 110 may include first and second side surfaces extending in the third direction D3, and a step surface connecting the first and second side surfaces.

The semiconductor pattern 120 may be disposed on the sidewall of the insulating structure 110 and the upper surface of the bit line BL. For example, the first liner semiconductor pattern 120 V1 and the second liner semiconductor pattern 120_V2 may be disposed on sidewalls of the insulating structure 110. Examples will be described mainly with reference to the first liner semiconductor pattern 120_V1.

The first liner semiconductor pattern 120_V1 may be disposed on a sidewall of the insulating structure 110. The first liner semiconductor pattern 120_V1 may include the first sub-semiconductor pattern 120_S1, the second sub-semiconductor pattern 120_S2, and the first connection semiconductor pattern 120_C1.

The first sub-semiconductor pattern 120_S1 may be disposed on the first side surface of the insulating structure 110. The first sub-semiconductor pattern 120_S1 may extend in the third direction D3 along the first side surface of the insulating structure 110. The second sub-semiconductor pattern 120_S2 may be disposed on the second side surface of the insulating structure 110. The second sub-semiconductor pattern 120_S2 may extend in the third direction D3 along the second side surface of the insulating structure 110. The first connection semiconductor pattern 120_C1 may be disposed on the step surface of the insulating structure 110. The first connection semiconductor pattern 120_C1 may connect the first sub-semiconductor pattern 120_S1 and the second sub-semiconductor pattern 120_S2.

The gate electrode 140 may be disposed on the semiconductor pattern 120. For example, the first sub-gate electrode may be disposed on the first liner semiconductor pattern 120_V1, and the second sub-gate electrode may be disposed on the second liner semiconductor pattern. The first sub-gate electrode may extend in the third direction D3. The first sub-gate electrode may be disposed at right angles with the upper surface of the bit line BL. The first sub-gate electrode may be substantially disposed at right angles with the upper surface of the bit line BL, for example, within about 1 to 10 degrees of a right angle. The gate insulating film 130 may be disposed between the gate electrode 140 and the semiconductor pattern 120.

The contact plug trench may be disposed between the insulating structure 110 and the gate separation pattern 160. In some embodiments, the width of the contact plug trench may be the same in the first direction D1. However, aspects are not limited thereto. The contact plug trench may have a tapered shape as illustrated in FIG. 2.

The contact plug 180 may be disposed on the contact plug trench. The contact plug 180 may be in contact with the second sub-semiconductor pattern 120_S2 and the first connection semiconductor pattern 120_C1, respectively. For example, a sidewall of the contact plug 180 may contact the second sub-semiconductor pattern 120_S2 and a lower surface of the contact plug 180 may contact the first connection semiconductor pattern 120_C1.

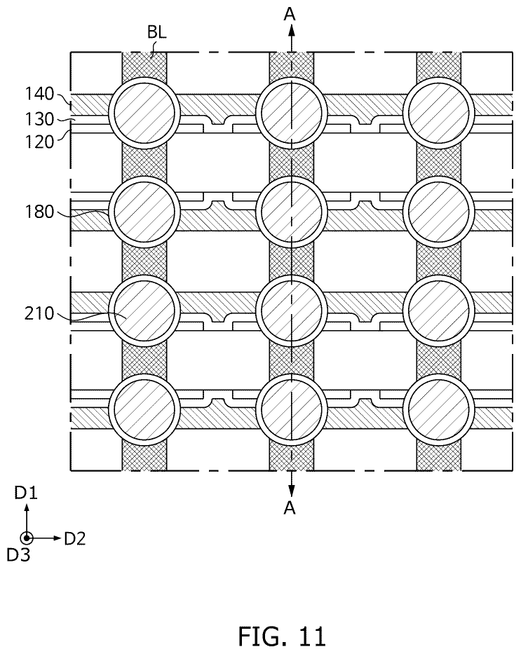

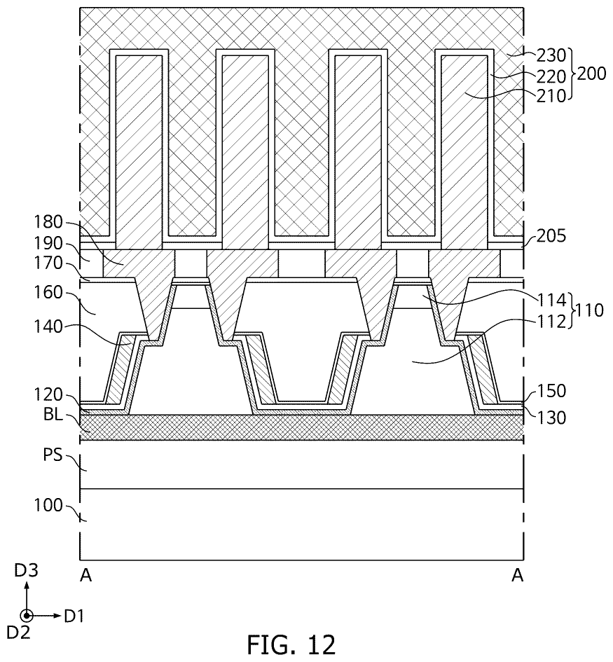

FIGS. 11 and 12 are diagrams provided to explain a semiconductor memory device according to some embodiments of the present disclosure. For reference, FIG. 11 is a plan view provided to explain the semiconductor memory device according to some embodiments, and FIG. 12 is a cross-sectional view taken along line A-A of FIG. 11.

Referring to FIGS. 11 and 12, the semiconductor memory device according to some embodiments may include the substrate 100, a peripheral structure PS, the bit line BL, the insulating structure 110, the semiconductor pattern 120, the gate insulating film 130, the gate electrode 140, the contact plug 180, and a capacitor structure C ST.

The substrate 100 may be a semiconductor substrate. For example, the substrate 100 may include silicon (Si), silicon germanium (SiGe), indium antimonide (InSb), lead telluride (PbTe), indium arsenide (InAs), indium phosphide (INP), gallium arsenide (GaAs), or gallium antimonide (GaSb). However, aspects are not limited to the above.

The peripheral structure PS may be disposed on the substrate 100. The peripheral structure PS may include a sensing transistor, a transmission transistor, or a driving transistor. However, aspects are not limited to the above. The type of the transistors disposed on the peripheral structure PS may vary depending on the layout design of the semiconductor device. The transistor in the peripheral structure PS may be electrically connected to the bit line BL through a conductive line.

The bit line BL may be disposed on the peripheral structure PS. The bit line BL may extend in the first direction DI on the peripheral structure PS. Adjacent bit lines BL may be spaced apart from each other in the second direction D2. A lower insulating layer may be disposed between the adjacent bit lines BL.

Descriptions of the insulating structure 110, the semiconductor pattern 120, the gate insulating film 130, the gate electrode 140, the gate separation liner 150, and the gate separation pattern 160 may be the same as those described above with reference to FIGS. 1 to 3.

The contact plug 180 may be disposed between the insulating structure 110 and the gate separation pattern 160. The contact plug 180 may be disposed on the semiconductor pattern 120. For example, the contact plug 180 may be disposed on the first liner semiconductor pattern (120_V1 of FIG. 3) and the second liner semiconductor pattern (120_V2 of FIG. 3), respectively. The contact plugs 180 may be spaced apart from each other in the first direction D1 and the second direction D2.

The contact plug 180 may electrically connect the semiconductor pattern 120 to a capacitor structure 200. For example, the capacitor structure 200 may be disposed on the contact plug 180. A lower electrode 210 of the capacitor structure 200 may be disposed on an upper surface of the contact plug 180. In some embodiments, the contact plug 180 may be referred to as a landing pad. When viewed in a plan view, the upper surface of the contact plug 180 may have various shapes such as a circle, an ellipse, a rectangle, a square, a rhombus, or a hexagon.

When viewed in the plan view, the contact plug 180 may be arranged in various forms such as a matrix form, a staggered form, or a honeycomb form along the first and second directions D1 and D2. The upper surface of the contact plug 180 may be placed in substantially the same plane as an upper surface of an interlayer insulating film 190, but aspects are not limited thereto. The interlayer insulating film 190 may be disposed between adjacent ones of the contact plugs 180. For example, the capacitor structure 200 may be disposed on the contact plug 180 and the interlayer insulating film 190.

The contact plug 180 may be formed of a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, or RuOₓ, or a combination thereof, but aspects are not limited thereto.

An etch stop layer 205 may be disposed on the contact plug 180 and the interlayer insulating film 190. The etch stop layer 205 may expose the contact plug 180. The etch stop layer 205 may be an etch stop film.

The capacitor structure 200 may be disposed on the contact plug 180 and the interlayer insulating film 190. The capacitor structure 200 may store a signal received from the transistor in the peripheral structure PS. The capacitor structure 200 may be used as a data storage element electrically connected to the transistor. For example, the capacitor structure 200 may store electric charges under the control of the transistor.

The capacitor structure 200 may include the lower electrode 210, a dielectric film 220, and an upper electrode 230.

The lower electrode 210 may be disposed on the contact plug 180. The lower electrode 210 may be electrically connected to the contact plug 180. A portion of the lower electrode 210 may be disposed in an etch stop layer 205. For example, the lower electrode 210 may penetrate the etch stop layer 205 and connected to the contact plug 180.

For example, the lower electrode 210 may include at least one of a conductive metal material (cobalt (Co), titanium (Ti), nickel (Ni), tungsten (W), or molybdenum (Mo)), a metal nitride (titanium nitride (TiN), or titanium silicon nitride (TiSiN), titanium aluminum nitride (TiAlN), tantalum aluminum nitride (TaAlN), or tungsten nitride (WN)), a noble metal material (platinum (Pt), ruthenium (Ru), or iridium (Ir)), a conductive oxide film (PtO, RuO₂, IrO₂, SrRuO₃ (SRO), (Ba,Sr)RuO₃ (BSRO), CaRuO₃ (CRO), or LSCO), or a metal silicide film. However, aspects are not limited to the above.

At least one supporter may be disposed between the lower electrodes 210. The supporter may support the lower electrode 210.

The dielectric film 220 may be disposed on the lower electrode 210. The dielectric film 220 may extend along the profile of the lower electrode 210. For example, the dielectric film 220 may include a high dielectric constant material including silicon oxide, silicon nitride, silicon oxynitride, and a metal. The dielectric film 220 may be a single film, but aspects are not limited thereto. In some examples, the dielectric film 220 may include a plurality of films.

The upper electrode 230 may be disposed on the dielectric film 220. The upper electrode 230 may fill at least a portion an empty space between the lower electrodes 210. For example, the upper electrode 230 may include at least one of an element semiconductor material film or a compound semiconductor material film. The upper electrode 230 may include a doped n-type or p-type impurity.

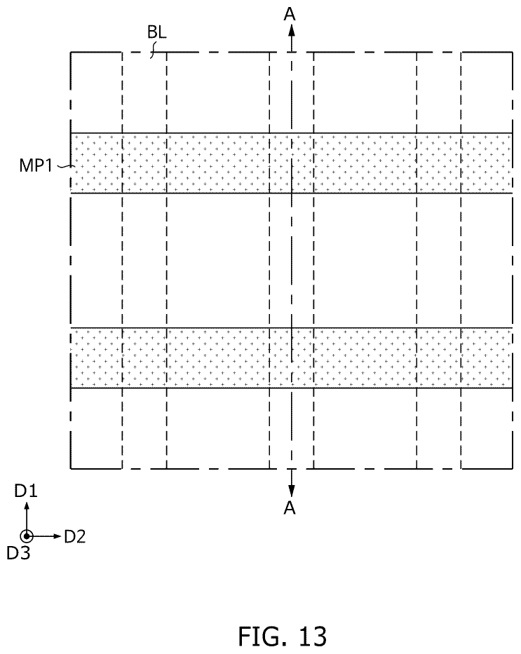

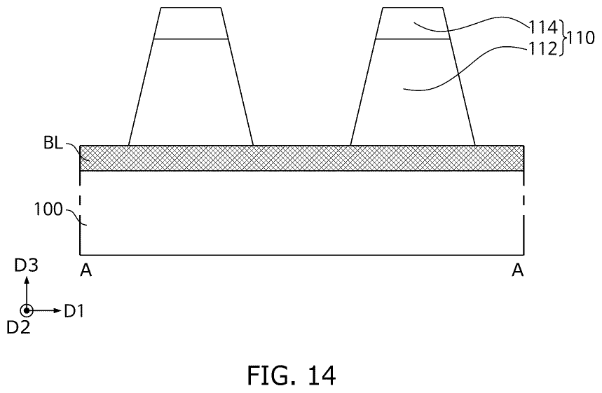

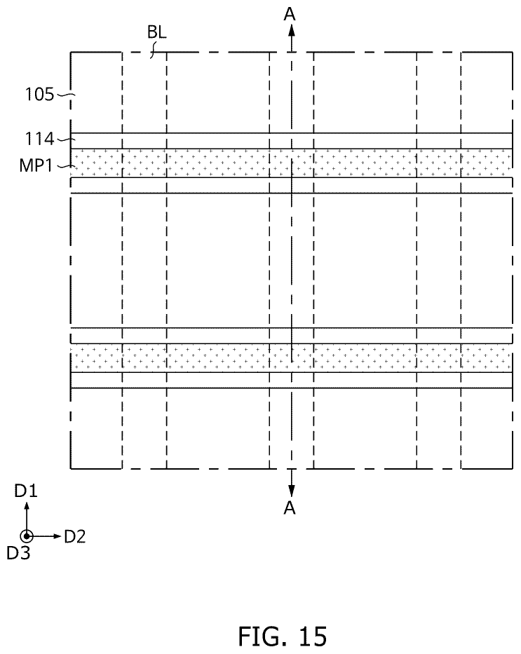

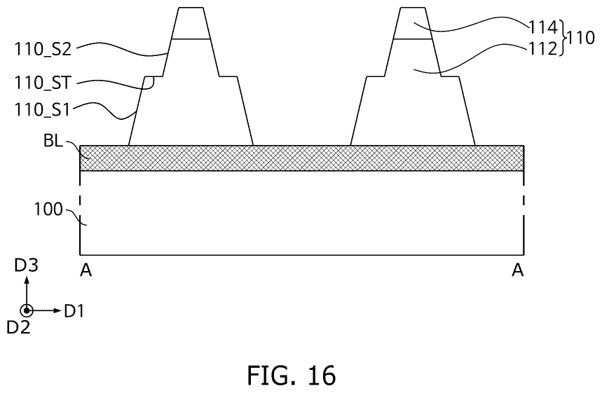

FIGS. 13 to 21 are diagrams showing one or more intermediate stages of a process, which are provided to explain a method for manufacturing a semiconductor device according to some embodiments of the present disclosure. For reference, FIGS. 13 and 15 are plan views showing one or more intermediate stages of process. FIG. 14 is a cross-sectional view taken along line A-A of FIG. 13, and FIGS. 16 to 21 are cross-sectional views taken along line A-A of FIG. 15.

Referring to FIGS. 13 and 14, the insulating structure 110 may be formed on the bit line BL and the lower insulating layer.

For example, the bit line BL and the lower insulating layer may be formed on the substrate 100. The bit lines BL may extend in the first direction D1. The adjacent bit lines BL may be spaced apart from each other in the second direction D2. A lower insulating layer may be disposed between the adjacent bit lines BL.

A first pre-insulating layer and a second pre-insulating layer may be stacked on the bit line BL and the lower insulating layer 105. The first pre-insulating layer may cover the bit line BL and the lower insulating layer. The second pre-insulating layer may be disposed on the first pre-insulating layer.

A first mask pattern MP1 may be formed on the second pre-insulating layer. The first mask pattern MP1 may extend in the second direction D2. The first mask pattern MP1 may overlap the second pre-insulating layer in the third direction D3. The first pre-insulating layer and the second pre-insulating layer may be etched by using the first mask pattern MP1 as an etch mask. The insulating structure 110 may be formed by etching process. The insulating structure 110 may include the first insulating layer 112 and the second insulating layer 114.

The insulating structure 110 may be spaced apart from each other in the first direction D1. The bit line BL and the lower insulating layer may be exposed between adjacent ones of the insulating structures 110.

Referring to FIGS. 15 and 16, the step surface 110_ST may be formed on the sidewall of the insulating structure 110.

For example, the second mask pattern MP2 may be formed on the second insulating layer 114 of the insulating structure 110. The second mask pattern MP2 may extend in the first direction D1. The second mask pattern MP2 may overlap the second insulating layer 114 in the third direction D3. The second mask pattern MP2 may cover a portion of the upper surface of the second insulating layer 114 while exposing a remaining portion.

The insulating structure 110 may be etched by using the second mask pattern MP2 as an etch mask. By the etching process, the upper portion of the insulating structure 110 may be etched, and the step surface 110_ST may be formed on the sidewall of the insulating structure 110. The step surface 110_ST may connect the first side surface 110_S1 and the second side surface 110_S2. A width of an upper portion of the insulating structure 110 in the first direction DI may decrease. For example, the width of the insulating structure 110 may be tapered in the third direction D3. The upper portion of the insulating structure 110 may be defined by the second insulating layer 114. The upper portion of the insulating structure 110 may be defined by the second insulating layer 114 and a portion of the first insulating layer 112.

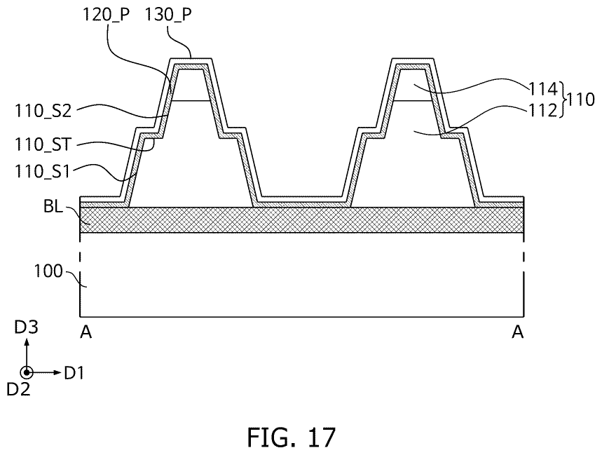

Referring to FIG. 17, a pre-semiconductor pattern 120_P and a pre-gate insulating film 130_P may be sequentially disposed on the insulating structure 110, the bit line BL, and the lower insulating layer.

For example, the pre-semiconductor pattern 120_P may be formed on sidewalls and the upper surface of the insulating structure 110, and on the upper surface of the bit line BL and the upper surface of the lower insulating layer. The pre-semiconductor pattern 120_P may extend along sidewalls of the insulating structure 110. For example, the pre-semiconductor pattern 120_P may extend along the first side surface 110_S1, the second side surface 110_S2, and the step surface 110_ST of the insulating structure 110.

In some embodiments, the pre-semiconductor pattern 120_P may be conformally formed on the sidewall of the insulating structure 110.

For example, the pre-semiconductor pattern 120_P may be formed using any one of physical vapor deposition (PVD), chemical vapor deposition (CVD), low pressure image vapor deposition (LP-CVD), plasma enhanced CVD (PE-CVD), and atomic layer deposition (ALD). However, aspects are not limited to the above.

The pre-gate insulating film 130_P may be formed on the pre-semiconductor pattern 120_P. The pre-gate insulating film 130_P may extend along the profile of the pre-semiconductor pattern 120_P. For example, the pre-gate insulating film 130_P may be formed using any one of physical vapor deposition (PVD), chemical vapor deposition (CVD), low pressure image vapor deposition (LP-CVD), plasma enhanced CVD (PE-CVD), and atomic layer deposition (ALD). However, aspects are not limited to the above.

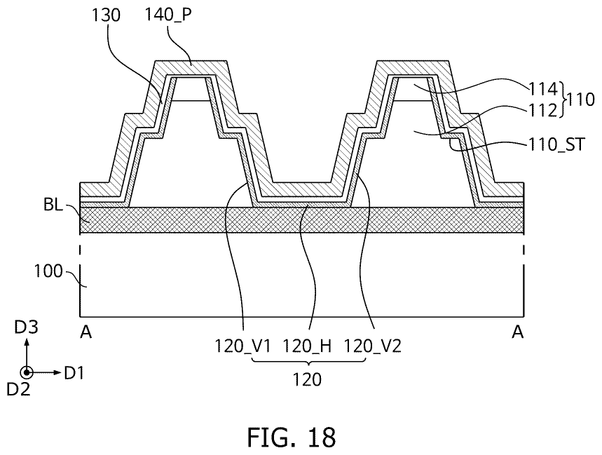

Referring to FIGS. 17 and 18, the semiconductor pattern 120, the gate insulating film 130, and a pre-gate electrode 140_P may be sequentially formed on the insulating structure 110.

For example, the pre-semiconductor pattern 120_P and the pre-gate insulating film 130_P disposed on the upper surface of the insulating structure 110 may be removed. As a result, the semiconductor pattern 120 may be disposed between the insulating structures 110 adjacent to each other in the first direction D1. In addition, a portion of the pre-semiconductor pattern 120_P extending in the second direction D2 may be removed, separating the pre-semiconductor pattern 120 Pin the second direction D2. That is, the semiconductor pattern 120 may be disposed between adjacent ones of the insulating structures 110 and may be spaced apart from each other in the second direction D2.

The gate insulating film 130 may be formed on the semiconductor pattern 120. In some embodiments, the thickness of the gate insulating film 130 may be greater than the thickness of the pre-gate insulating film 130_P. The gate insulating film 130 may be disposed on the upper surface of the insulating structure 110.

The pre-gate electrode 140_P may be formed. The pre-gate electrode 140_P may be disposed on the gate insulating film 130. The pre-gate electrode 140_P may be formed along the profile of the gate insulating film 130.

For example, the pre-gate electrode 140_P may be formed using any one of physical vapor deposition (PVD), chemical vapor deposition (CVD), low pressure image vapor deposition (LP-CVD), plasma enhanced CVD (PE-CVD), and atomic layer deposition (ALD).

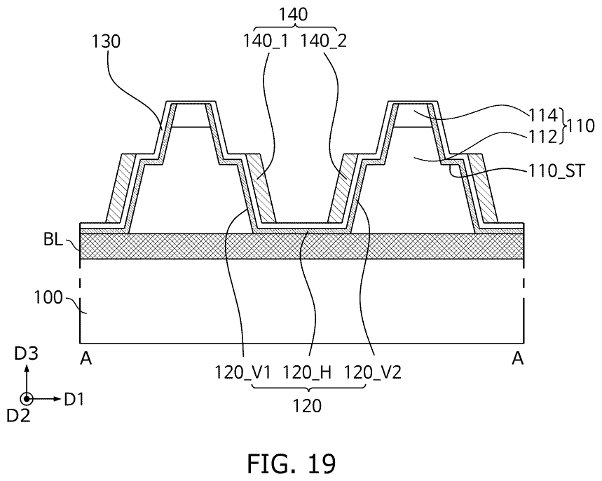

Referring to FIGS. 18 and 19, a portion of the pre-gate electrode 140_P may be removed and the gate electrode 140 may be formed.

For example, a portion of the pre-gate electrode 140_P may be removed by etching process. For example, the upper surface and the step surface 110_ST of the insulating structure 110 and the pre-gate electrode 140_P disposed on the upper surface of the bit line BL may be removed. As a result, the pre-gate electrodes 140_P may be spaced apart from each other in the first direction D1.

In some embodiments, a portion of the gate insulating film 130 may be removed while the pre-gate electrode 140_P disposed on the upper surface of the bit line BL is removed. In this case, the gate insulating film 130 may be spaced apart in the first direction D1 like the gate electrode 140.

A spin on hardmask (SOH) may be formed on the pre-gate electrode 140_P. The SOH may be etched, exposing a portion of the pre-gate electrode 140_P. The gate electrode 140 may be formed by removing the exposed portion of the pre-gate electrode 140_P. For example, the pre-gate electrode 140_P disposed on the step surface 110_ST of the insulating structure 110 may be removed so that the gate electrode 140 may be formed.

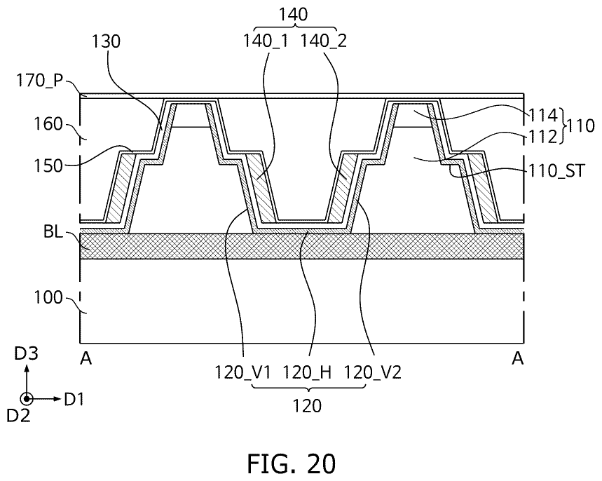

Referring to FIG. 20, the gate separation liner 150 and the gate separation pattern 160 may be formed on the gate electrode 140, and a pre-capping layer 170_P may be formed on the gate separation pattern 160.

For example, the gate separation liner 150 may be formed on the side surface and the upper surface of the gate electrode 140. The gate separation liner 150 may be disposed along the gate insulating film 130 and the gate electrode 140.

The gate separation pattern 160 may be formed on the gate separation liner 150. The gate separation pattern 160 may fill at least a portion a space between the insulating structures 110. The pre-capping layer 170_P may be formed on the gate separation pattern 160.

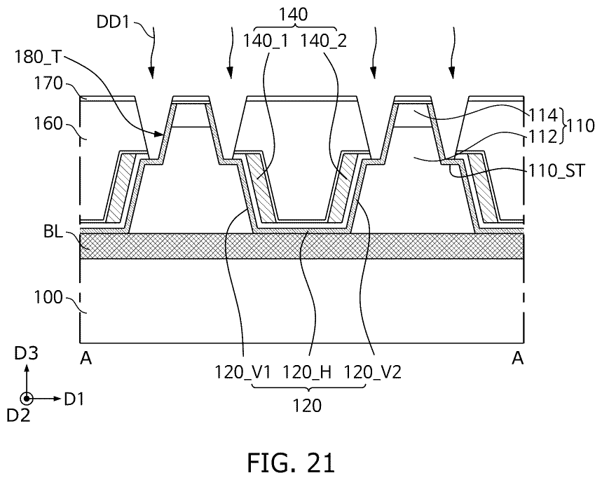

Referring to FIGS. 20 and 21, the pre-capping layer 170_P and the gate separation pattern 160 may be etched to form the contact plug trench 180_T.

For example, a third mask pattern may be formed above the pre-capping layer 170_P. The pre-capping layer 170_P and the gate separation pattern 160 may be etched by using the third mask pattern as an etching mask. By the etching process, the contact plug trench 180_T may be formed.

The contact plug trench 180_T may expose the first liner semiconductor pattern 120_V1 and the second liner semiconductor pattern 120_V2. For example, the contact plug trench 180_T may expose a portion of the first liner semiconductor pattern 120_V1 and a portion of the second liner semiconductor pattern 120_V2, which are disposed on and above the step surface 110_ST.

A first doping process DD1 may be performed on the contact plug trench 180_T. For example, the first doping process DD1 may be a process of injecting tungsten (W) ions. The first doping process DD1 may increase the concentration of tungsten (W) of the semiconductor pattern 120 exposed to the contact plug trench 180_T. Accordingly, electrical characteristics of the transistor that uses the semiconductor pattern 120 as a channel can be improved.

Referring to FIG. 3, the contact plug 180 may be formed on the contact plug trench 180_T. The contact plug 180 may fill at least a portion the contact plug trench 180_T.

In some embodiments, the contact plug 180 may be separated by etching process. For example, the contact plugs 180 may be spaced apart from each other in the first direction DI and the second direction D2 as illustrated in FIG. 12.

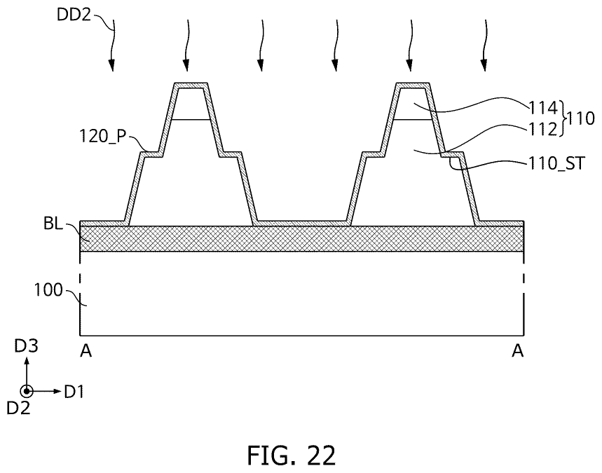

FIG. 22 is a diagram showing an intermediate stage of process, provided to explain a method for manufacturing a semiconductor device according to some embodiments of the present disclosure. For reference, FIG. 22 may be a manufacturing method performed after FIGS. 13 to 16.

Referring to FIG. 22, the pre-semiconductor pattern 120_P may be formed on the insulating structure 110, the bit line BL, and the lower insulating layer.

For example, the pre-semiconductor patterns 120_P may be formed on sidewalls and the upper surface of the insulating structure 110, and on the upper surface of the bit line BL and the upper surface of the lower insulating layer. The pre-semiconductor pattern 120_P may extend along sidewalls of the insulating structure 110. For example, the pre-semiconductor pattern 120_P may extend along the first side surface 110_S1, the second side surface 110_S2, and the step surface 110_ST of the insulating structure 110.

A second doping process DD2 may be performed on the pre-semiconductor pattern 120_P. For example, the second doping process DD2 may be a process of injecting tungsten (W) ions. The second doping process DD2 may increase the concentration of tungsten (W) in the pre-semiconductor pattern 120_P.

A pre-gate insulating film may be formed on the pre-semiconductor pattern 120_P. The pre-gate insulating film may extend along the profile of the pre-semiconductor pattern 120_P. The pre-gate insulating film may be formed into a shape as shown in FIG. 17.

The subsequent process of the manufacturing method may be identical to the process described above with reference to FIGS. 18 to 21. In some embodiments, the first doping process DD1 described in FIG. 21 may be omitted.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

1. A semiconductor device comprising:
a bit line extending in a first horizontal direction;
a plurality of insulating structures disposed on the bit line and spaced apart from each other in the first horizontal direction;
a semiconductor pattern disposed on sidewalls of the plurality of insulating structures;
a gate electrode disposed on the semiconductor pattern and extending in a second horizontal direction intersecting the first horizontal direction;
a gate insulating film disposed between the gate electrode and the semiconductor pattern; and
a contact plug disposed in contact with the semiconductor pattern along the sidewall of an insulating structure of the plurality of insulating structures.

2. The semiconductor device according to claim 1, wherein the sidewalls of the plurality of insulating structures include a first side surface, a second side surface, and a step surface connecting the first side surface and the second side surface, and
the semiconductor pattern includes a first sub-semiconductor pattern disposed on the first side surface, a second sub-semiconductor pattern disposed on the second side surface, and a connection semiconductor pattern disposed on the step surface.

3. The semiconductor device according to claim 2, wherein the gate electrode is disposed on the first sub-semiconductor pattern.

4. The semiconductor device according to claim 2, wherein a portion of the contact plug overlaps the semiconductor pattern in the first horizontal direction and the contact plug is in contact with the second sub-semiconductor pattern.

5. The semiconductor device according to claim 2, wherein a doping concentration of an element in the first sub-semiconductor pattern is lower than a doping concentration of the element in the second sub-semiconductor pattern.

6. The semiconductor device according to claim 1, wherein a portion of the contact plug overlaps the gate electrode in the first horizontal direction.

7. The semiconductor device according to claim 2, wherein, with respect to an upper surface of the bit line, an upper surface of the gate electrode is disposed higher than the step surface of the plurality of insulating structures.

8. The semiconductor device according to claim 1, further comprising a capping layer disposed on upper surfaces of the plurality of insulating structures and an upper surface of the semiconductor pattern.

9. The semiconductor device according to claim 1, wherein the gate electrode includes a first sub-gate electrode and a second sub-gate electrode spaced apart from the first sub-gate electrode in the first horizontal direction, and
the semiconductor device further includes a gate separation pattern disposed between the first sub-gate electrode from the second sub-gate electrode.

10. The semiconductor device according to claim 9, wherein the contact plug is disposed between the gate separation pattern and the plurality of insulating structures.

11. The semiconductor device according to claim 1, wherein each of the plurality of insulating structures includes a first insulating layer disposed on the bit line and a second insulating layer disposed on the first insulating layer, and
the second insulating layer is disposed above a step surface of the plurality of insulating structures.

12. The semiconductor device according to claim 11, wherein each of the plurality of insulating structures further includes a third insulating layer disposed between the bit line and the first insulating layer, and
the third insulating layer includes silicon nitride.

13. A semiconductor device, comprising:
a bit line extending in a first horizontal direction;
a plurality of insulating structures disposed on the bit line and spaced apart from each other in the first horizontal direction;
a semiconductor pattern disposed on the plurality of insulating structures, wherein the semiconductor pattern includes a first liner semiconductor pattern and a second liner semiconductor pattern spaced apart from each other in the first horizontal direction;
a gate electrode disposed on the semiconductor pattern and extending in a second horizontal direction intersecting the first horizontal direction;
a gate insulating film disposed between the semiconductor pattern and the gate electrode; and
a contact plug disposed on the semiconductor pattern,
wherein the contact plug is in contact with at least one of a side surface of the first liner semiconductor pattern or a side surface of the second liner semiconductor pattern.

14. The semiconductor device according to claim 13, wherein opposite sidewalls of a first insulating structure of the plurality of insulating structures each include a step surface, and
the first liner semiconductor pattern and the second liner semiconductor pattern extend along the opposite sidewalls of the first insulating structure.

15. The semiconductor device according to claim 14, wherein the contact plug vertically overlaps the step surfaces of the first insulating structure.

16. The semiconductor device according to claim 13, wherein the semiconductor pattern further includes a horizontal semiconductor pattern connecting the first liner semiconductor pattern and the second liner semiconductor pattern, and
the horizontal semiconductor pattern extends along the bit line.

17. The semiconductor device according to claim 16, wherein the bit line includes a recess disposed between the plurality of insulating structures, and
the horizontal semiconductor pattern is disposed on the recess.

18. The semiconductor device according to claim 13, wherein the gate electrode includes a first sub-gate electrode disposed on the first liner semiconductor pattern and a second sub-gate electrode disposed on the second liner semiconductor pattern, and
the first sub-gate electrode and the second sub-gate electrode are spaced apart from each other in the first horizontal direction.

19. The semiconductor device according to claim 13, further comprising a capping layer disposed on the plurality of insulating structures and the semiconductor pattern,
wherein a portion of the capping layer overlaps the semiconductor pattern in a third direction, and
the third direction is a direction perpendicular to an upper surface of the bit line.

20. A semiconductor memory device comprising:
a bit line extending in a first horizontal direction;
a plurality of insulating structures disposed on the bit line and spaced apart from each other in the first horizontal direction, wherein sidewalls of the plurality of insulating structures include a first side surface, a second side surface, and a step surface connecting the first side surface and the second side surface;
a semiconductor pattern disposed on the sidewalls of the plurality of insulating structures, wherein the semiconductor pattern includes a first sub-semiconductor pattern disposed on the first side surface, a second sub-semiconductor pattern disposed on the second side surface, and a connection semiconductor pattern disposed on the step surface;
a gate electrode disposed on the first sub-semiconductor pattern and extending in a second horizontal direction intersection the first horizontal direction;
a gate insulating film disposed between the gate electrode and the semiconductor pattern;
a contact plug in contact with the second sub-semiconductor pattern; and
a capacitor structure connected to the contact plug,
wherein a portion of the contact plug overlaps the second sub-semiconductor pattern in the first horizontal direction.
